(19) United States
(12) Patent Application Publication
(10) Pub. No.: US 2017/0264319 A1
(43) Pub. Date: Sep. 14, 2017

(54) DECODING DEVICE, INFORMATION TRANSMISSION SYSTEM, DECODING METHOD, AND NON-TRANSITORY COMPUTER READABLE MEDIUM

(71) Applicant: FUJI XEROX CO., LTD., Tokyo (JP)

(72) Inventor: Tsutomu HAMADA, Kanagawa (JP)

(73) Assignee: FUJI XEROX CO., LTD., Tokyo (JP)

(21) Appl. No.: 15/231,917

(22) Filed: Aug. 9, 2016

(30) Foreign Application Priority Data
Mar. 11, 2016 (JP) 2016-048425

(51) Int. Cl. H03M 13/15; H04L 1/00

(52) U.S. Cl. CPC H03M 13/1575; H04L 1/0047; H03M 13/157

(57) ABSTRACT

A decoding device receives transmission data obtained by scrambling according to a polynomial x^{a}+x^{b}+1 where a and b are each an integer, a>b, and a≠2b. The decoding device includes a receiving unit, an error detecting unit, and a correcting unit. The receiving unit receives data obtained by performing scrambling for a block in which an error correcting code has been added to the transmission data of (n−8) bits where n<a. The error detecting unit calculates, on the basis of a table, an error location in descrambled data obtained by descrambling the received data. The correcting unit corrects the descrambled data at the error location calculated by the error detecting unit.

### CROSS-REFERENCE TO RELATED APPLICATIONS

This application is based on and claims priority under 35 USC 119 from Japanese Patent Application No. 2016-048425 filed Mar. 11, 2016.

### BACKGROUND

### Technical Field

The present invention relates to a decoding device, an information transmission system, a decoding method, and a non-transitory computer readable medium.

### SUMMARY

According to an aspect of the invention, there is provided a decoding device that receives transmission data obtained by scrambling according to a polynomial x^{a}+x^{b}+1 where a and b are each an integer, a>b, and a≠2b. The decoding device includes a receiving unit, an error detecting unit, and a correcting unit. The receiving unit receives data obtained by performing scrambling for a block in which an error correcting code has been added to the transmission data of (n−8) bits where n<a, the error correcting code being calculated according to a cyclic code generator polynomial x⁸+x⁶+x⁴+x³+1. The error detecting unit calculates, on the basis of a table, an error location in descrambled data obtained by descrambling the received data, in accordance with an error pattern corresponding to a syndrome calculated on the basis of the error correcting code from the descrambled data and an error correcting code calculated from the descrambled data, the table including syndromes and bit error location numbers that are associated with each other in advance where a syndrome corresponding to a bit error location number P1 representing 2-bit error locations p where p≦n and p+b including a 1-bit error location p and a 1-bit error location p+b is indicated by an exclusive OR of a syndrome corresponding to the 1-bit error location p and a syndrome corresponding to the 1-bit error location p+b, a syndrome corresponding to a bit error location number P2 representing 2-bit error locations p and p+(a−b) including the 1-bit error location p and a 1-bit error location p+(a−b) is indicated by an exclusive OR of a syndrome corresponding to the 1-bit error location p and a syndrome corresponding to the 1-bit error location p+(a−b), and the syndromes and the bit error location numbers are associated with each other in such a manner that the bit error location number P1 and the bit error location number P2 satisfy P1, P2>n and |P1−P2|>n. The correcting unit corrects the descrambled data at the error location calculated by the error detecting unit.

### BRIEF DESCRIPTION OF THE DRAWINGS

An exemplary embodiment of the present invention will be described in detail based on the following figures, wherein:

FIG. 1 schematically illustrates an exemplary configuration of an information transmission system according to the exemplary embodiment of the present invention;

FIG. 2 is a block diagram illustrating an exemplary configuration of an encoding device according to the exemplary embodiment of the present invention;

FIG. 3 illustrates exemplary forward error correction (FEC) blocks;

FIG. 4A illustrates an FEC block, and FIG. 4B illustrates generation of an error correcting code;

FIG. 5 is a block diagram illustrating an exemplary configuration of a decoding device according to the exemplary embodiment of the present invention;

FIG. 6 illustrates calculation of a syndrome;

FIG. 7 illustrates error patterns;

FIGS. 8A, 8B, and 8C illustrate syndromes and error locations;

FIG. 9 illustrates an exemplary table in which syndromes and error location numbers are associated with each other;

FIG. 10 illustrates details of an encoding routine executed by the encoding device according to the exemplary embodiment of the present invention; and

FIG. 11 illustrates details of a decoding routine executed by the decoding device according to the exemplary embodiment of the present invention.

### DETAILED DESCRIPTION

An exemplary embodiment of the present invention will be described below with reference to the drawings. The following description illustrates the case where the exemplary embodiment of the present invention is applied to an information transmission system in which information is transmitted and received between two devices by serial transmission.

Information Transmission System

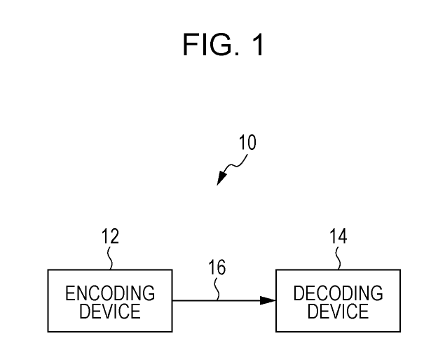

First, a schematic configuration of an information transmission system according to the exemplary embodiment of the present invention will be described. FIG. 1 schematically illustrates an exemplary configuration of the information transmission system according to the exemplary embodiment of the present invention. As illustrated in FIG. 1, an information transmission system 10 includes an encoding device 12 that transmits information and a decoding device 14 that receives the information.

The encoding device 12 and the decoding device 14 are connected to each other via a transmission path 16. The transmission path 16 is a transmission path used to transmit information from the encoding device 12 to the decoding device 14 by serial transmission.

Encoding Device

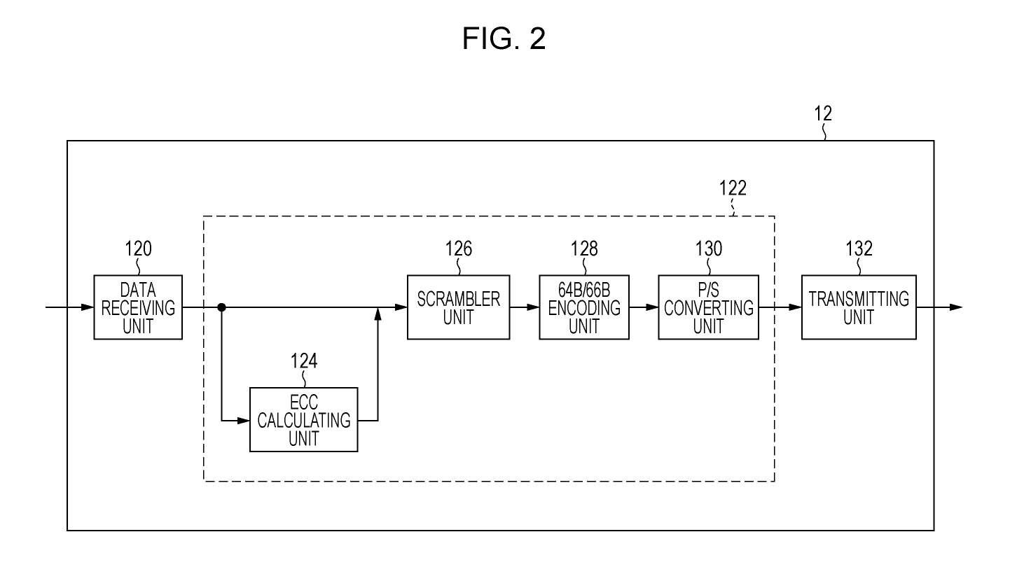

Next, a configuration of the encoding device 12 will be described. FIG. 2 is a block diagram illustrating an exemplary configuration of the encoding device 12. As illustrated in FIG. 2, the encoding device 12 includes a data receiving unit 120, a converting unit 122, and a transmitting unit 132. The encoding device 12 is implemented by a circuit (integrated circuit (IC)), such as a field programmable gate array (FPGA), an application specific integrated circuit (ASIC), or a gate array. Each of the above functional units included in the encoding device 12 may be realized by a computer including a central processing unit (CPU), a random access memory (RAM), a read only memory (ROM), and the like, and each function of each of the functional units may be executed by the CPU executing a corresponding program stored in the ROM.

The data receiving unit 120 receives parallel transmission data. The exemplary embodiment describes, as an example, the case of using parallel transmission block data of 56 bits.

The converting unit 122 acquires the parallel transmission block data received by the data receiving unit 120. The converting unit 122 then adds an error correcting code (ECC) to the acquired transmission data and encodes the 64 bit transmission data to produce 66 bit encoded data. As illustrated in FIG. 2, the converting unit 122 includes an ECC calculating unit 124, a scrambler unit 126, a 64B/66B encoding unit 128, and a parallel-to-serial (P/S) converting unit 130.

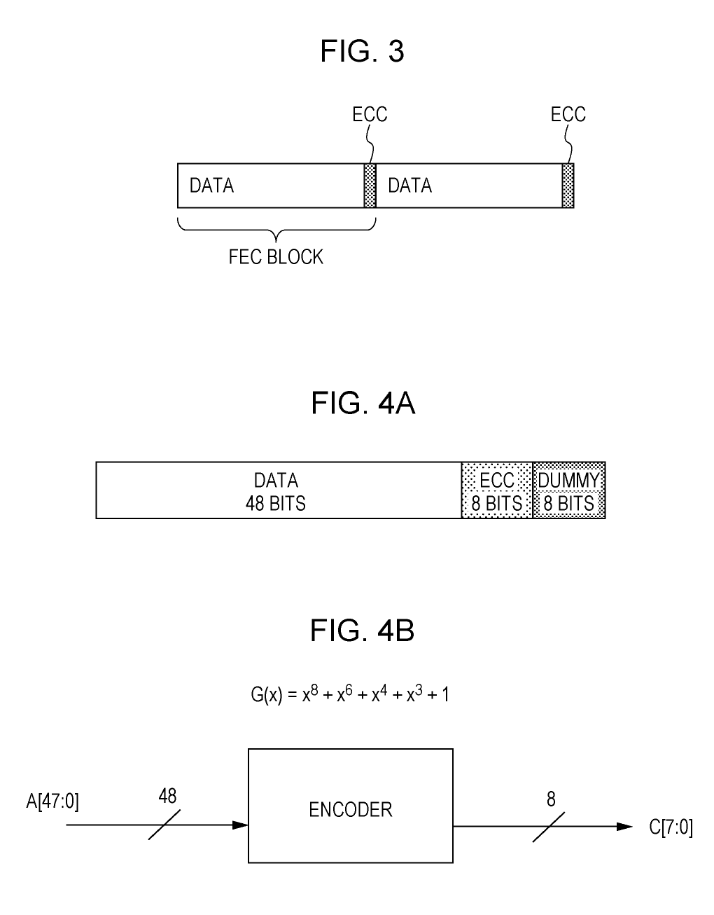

The ECC calculating unit 124 calculates the error correcting code to be added to the transmission data according to the parallel transmission data received by the data receiving unit 120 and a preset cyclic code generator polynomial. FIG. 3 illustrates examples of transmission data and error correcting codes according to the exemplary embodiment. In the manner illustrated in FIG. 3, the error correcting code is added to the transmission data by the ECC calculating unit 124, which will be described later.

FIG. 4A illustrates a forward error correction (FEC) block, and FIG. 4B illustrates generation of an error correcting code. In the exemplary embodiment, as illustrated in FIG. 4A, an error correcting code (8 bits) is calculated from transmission data of 48 bits (6 bytes). An FEC block has 64 bits (8 bytes) in total, including the remaining 8 bits as dummy bits, e.g., “00000000”. Note that the transmission data of 48 bits (6 bytes) is an example of a block.

As illustrated in FIG. 4B, the ECC calculating unit 124 calculates, as the error correcting code, the remainder by dividing a bit stream of the transmission data by an eight-degree cyclic code generator polynomial G(x) represented by the following Expression (1).

G(x)=x⁸+x⁶+x⁴+x³+1 (1)

FIG. 4B illustrates the transmission data of 48 bits being input to the ECC calculating unit 124. Specifically, the ECC calculating unit 124 calculates the error correcting code according to the following Expressions (2).

C7=A1+A3+A4+A8+A9+A12+A13+A14+A21+A22+A23+A24+A25+A27+A30+A32+A34+A37+A43

C6=A0+A2+A3+A7+A8+A11+A12+A13+A20+A21+A22+A23+A24+A26+A29+A31+A33+A36+A42+A47

C5=A2+A3+A4+A6+A7+A8+A9+A10+A11+A13+A14+A19+A20+A24+A27+A28+A34+A35+A37+A41+A43+A46+A47

C4=A1+A2+A3+A5+A6+A7+A8+A9+A10+A12+A13+A18+A19+A23+A26+A27+A33+A34+A36+A40+A42+A45+A46

C3=A0+A1+A2+A4+A5+A6+A7+A8+A9+A11+A12+A17+A18+A22+A25+A26+A32+A33+A35+A39+A41+A44+A45+A47

C2=A0+A5+A6+A7+A9+A10+A11+A12+A13+A14+A16+A17+A22+A23+A27+A30+A31+A37+A38+A40+A44+A46

C1=A1+A3+A5+A6+A10+A11+A14+A15+A16+A23+A24+A25+A26+A27+A29+A32+A34+A36+A39+A45

C0=A0+A2+A4+A5+A9+A10+A13+A14+A15+A22+A23+A24+A25+A26+A28+A31+A33+A35+A38+A44 (2)

Expressions (2) are used to calculate an error correcting code for an input of 48 bits where Axx denotes an xx-th bit in the input of the transmission data and Cx denotes an x-th bit in the output of the error correcting code. In addition, the symbol “+” here indicates an exclusive OR (XOR) operation.

The scrambler unit 126 receives transmission data and the error correcting code that has been added to the transmission data, the transmission data having been received by the data receiving unit 120, and scrambles the transmission data and the error correcting code according to a polynomial x^{a}+x^{b}+1 (where a and b are each an integer, a>b, and a≠2b).

In the exemplary embodiment, the sum, represented as n, of the number of bits of the transmission data and the number of bits of the error correcting code, is less than the index a (n<a) in the above polynomial. In the exemplary embodiment, since the error correcting code has 8 bits, the transmission data has (n−8) bits.

For example, the scrambler unit 126 scrambles, according to the following Expression (3), the transmission data and the error correcting code that has been added to the transmission data. The following Expression (3) denotes the case where the index a is 58 and the index b is 39 in the polynomial.

G(x)=x⁵⁸+x³⁹+1 (3)

The 64B/66B encoding unit 128 encodes, in accordance with a predetermined encoding scheme, the transmission data scrambled by the scrambler unit 126 and transforms the number of bits. The exemplary embodiment illustrates, as an example, the case of encoding in accordance with a 64B/66B encoding scheme with the number of bits transformed.

The parallel-to-serial (P/S) converting unit 130 converts the parallel data of 66 bits, obtained as a result of transformation performed by the 64B/66B encoding unit 128, to a serial bit stream by parallel to serial (P/S) conversion. In the exemplary embodiment, FEC blocks in each of which dummy bits (8 bits) and the error correcting code (8 bits) have been added to the transmission data (64 bits) are sequentially subjected to 64B/66B transformation, then subjected to parallel to serial conversion, and transmitted as data by the transmitting unit 132, which will be described later.

The transmitting unit 132 outputs, to the transmission path 16, the serial data obtained as a result of conversion performed by the parallel-to-serial (P/S) converting unit 130. The transmitting unit 132 may be connected to a photoelectric converter (not illustrated) in order to convert the electric output to an optical output. In this case, the transmission path 16 is formed of optical fibers or the like.

Decoding Device

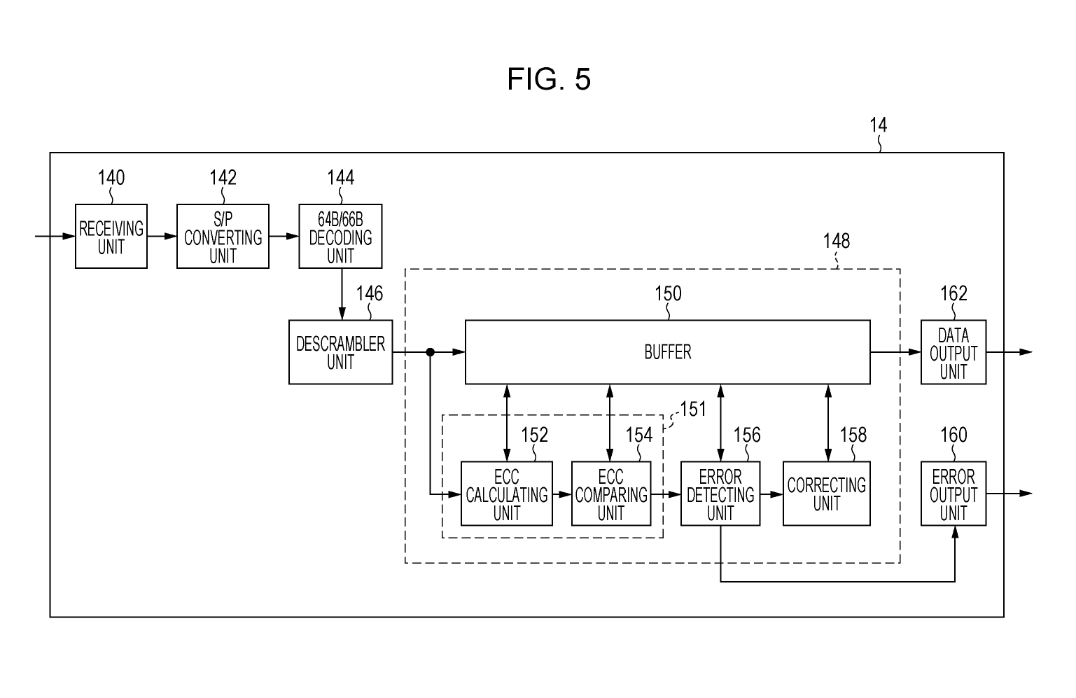

Next, a configuration of the decoding device 14 will be described. FIG. 5 is a block diagram illustrating an exemplary configuration of the decoding device 14. As illustrated in FIG. 5, the decoding device 14 includes a receiving unit 140, a serial-to-parallel (S/P) converting unit 142, a 64B/66B decoding unit 144, a descrambler unit 146, an error correcting unit 148, an error output unit 160, and a data output unit 162. The decoding device 14 is implemented by a circuit (integrated circuit (IC)), such as a field programmable gate array (FPGA), an application specific integrated circuit (ASIC), or a gate array. Each of the above functional units included in the decoding device 14 may be realized by a computer including a central processing unit (CPU), a random access memory (RAM), a read only memory (ROM), and the like, and each function of each of the functional units may be executed by the CPU executing a corresponding program stored in the ROM.

The receiving unit 140 receives serial data transmitted from the encoding device 12 through the transmission path 16. In the case of receiving an optical output, the receiving unit 140 is connected to a photoelectric converter (not illustrated) and receives an electric output converted from the optical output as the serial data.

The serial-to-parallel (S/P) converting unit 142 converts the serial data received by the receiving unit 140 to parallel data.

The 64B/66B decoding unit 144 decodes, in accordance with a 64B/66B encoding scheme with the number of bits transformed, the parallel data obtained by the serial-to-parallel (S/P) converting unit 142 and outputs the resulting data as received data and an error correcting code.

The descrambler unit 146 descrambles the received data and error correcting code decoded by the 64B/66B decoding unit 144. Note that the descrambling is performed according to the polynomial represented by the above Expression (3). In addition, the descrambler unit 146 causes the resulting descrambled data and error correcting code to be stored in a buffer 150, which will be described later.

The error correcting unit 148 includes the buffer 150, an ECC unit 151, an error detecting unit 156, and a correcting unit 158.

The buffer 150 stores the descrambled data and error correcting code obtained by the descrambler unit 146.

The ECC unit 151 calculates a syndrome from the descrambled data and error correcting code stored in the buffer 150. The ECC unit 151 includes an ECC calculating unit 152 and an ECC comparing unit 154.

The ECC calculating unit 152 acquires the descrambled data stored in the buffer 150 and calculates an error correcting code on the basis of the acquired descrambled data and according to the cyclic code generator polynomial G(x) represented by the above Expression (1). Specifically, in the same manner as the ECC calculating unit 124, the ECC calculating unit 152 calculates, as the error correcting code, the remainder by dividing a bit stream of the descrambled data by the 8-degree cyclic code generator polynomial G(x) represented by the above Expression (1).

The ECC comparing unit 154 calculates a syndrome on the basis of the error correcting code stored in the buffer 150 and the error correcting code calculated by the ECC calculating unit 152.

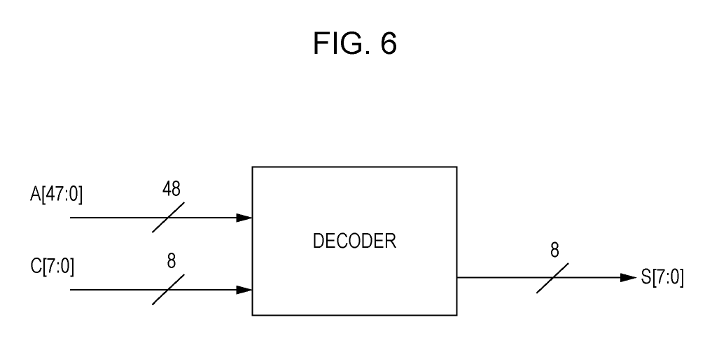

FIG. 6 illustrates an exemplary process performed by the ECC unit 151. For example, as illustrated in FIG. 6, the ECC unit 151 calculates a syndrome S[7:0] from an error correcting code C[7:0] stored in the buffer 150 and descrambled data A[47:0] stored in the buffer 150. The expression for syndrome calculation is represented by the following Expressions (4).

S7=C7+A1+A3+A4+A8+A9+A12+A13+A14+A21+A22+A23+A24+A25+A27+A30+A32+A34+A37+A43

S6=C6+A0+A2+A3+A7+A8+A11+A12+A13+A20+A21+A22+A23+A24+A26+A29+A31+A33+A36+A42+A47

S5=C5+A2+A3+A4+A6+A7+A8+A9+A10+A11+A13+A14+A19+A20+A24+A27+A28+A34+A35+A37+A41+A43+A46+A47

S4=C4+A1+A2+A3+A5+A6+A7+A8+A9+A10+A12+A13+A18+A19+A23+A26+A27+A33+A34+A36+A40+A42+A45+A46

S3=C3+A0+A1+A2+A4+A5+A6+A7+A8+A9+A11+A12+A17+A18+A22+A25+A26+A32+A33+A35+A39+A41+A44+A45+A47

S2=C2+A0+A5+A6+A7+A9+A10+A11+A12+A13+A14+A16+A17+A22+A23+A27+A30+A31+A37+A38+A40+A44+A46

S1=C1+A1+A3+A5+A6+A10+A11+A14+A15+A16+A23+A24+A25+A26+A27+A29+A32+A34+A36+A39+A45

S0=C0+A0+A2+A4+A5+A9+A10+A13+A14+A15+A22+A23+A24+A25+A26+A28+A31+A33+A35+A38+A44 (4)

In the above Expressions (4), Axx denotes an xx-th bit in the input of the descrambled data, Cx denotes an x-th bit in the error correcting code, and Sx denotes an x-th bit in the output of the syndrome. In addition, the symbol “+” here indicates an exclusive OR (XOR) operation. If all the bits in the syndrome Sx are zero values, it is determined that there is no bit error. If a bit in the syndrome Sx is not a zero value, the bit error location is specified by the error detecting unit 156, which will be described later.

From the syndrome calculated by the ECC comparing unit 154 and on the basis of a table in which syndromes and bit error locations are associated with each other in advance, the error detecting unit 156 detects a bit error location in accordance with an error pattern corresponding to the above syndrome.

Specifically, the error detecting unit 156 detects a bit error on the transmission path other than in the case where the syndrome calculated by the ECC comparing unit 154 is all zero values. Then, the error detecting unit 156 specifies an error pattern.

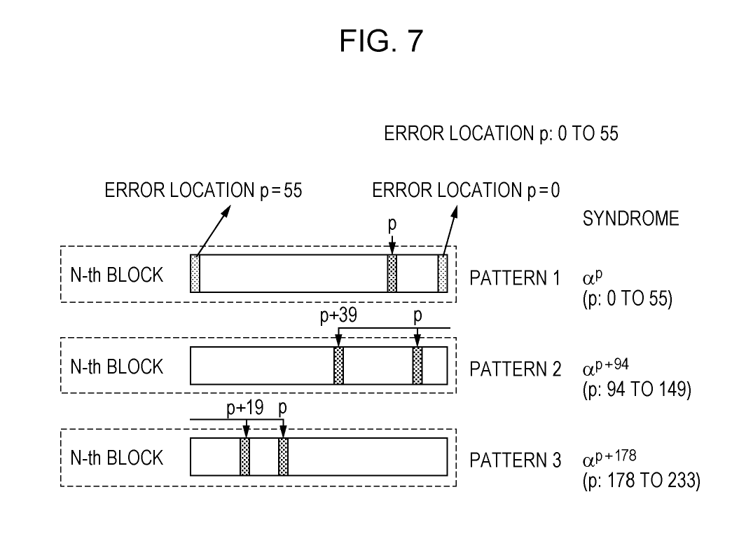

FIG. 7 illustrates exemplary error patterns obtained if a 1-bit error occurs on the transmission path. As illustrated in FIG. 7, the 1-bit error on the transmission path is spread to another bit by descrambling, and the 1-bit error leads to an error of 2 or less bits. Note that the dummy bits are omitted from illustration of the FEC block in FIG. 7.

As illustrated in FIG. 7, in Error Pattern 1, the FEC block includes a 1-bit error, and an error location number P corresponding to a syndrome is in the range of 0 to 55, which directly corresponds to an error location p. The syndrome corresponding to the P-th error location is indicated as α^{P}, and the error location number P corresponding to the syndrome and the actual bit error location p correspond to each other. Note that the bit error location number P will be described later in detail.

On the other hand, in Error Patterns 2 and 3, the error location numbers P corresponding to the syndromes and error locations p do not correspond to each other. Accordingly, the error locations p are obtained from the error location numbers P corresponding to the syndromes. Note that each of the error locations p is less than or equal to the number of bits of the transmission data and error correcting code (p≦n).

For example, in Error Pattern 2, the error location number P corresponding to the syndrome is in the range of 94 to 149, and the numbers therein are all greater than the number of data bits, which is 56. Thus, the error location number P corresponding to the syndrome and the error location p do not correspond to each other. Here, in Error Pattern 2, if the FEC block includes an error of 2 bits and the syndrome is indicated as α^{P+94}, the error locations are p and p+39. Note that, if the polynomial used for scrambling is the polynomial x^{a}+x^{b}+1, the bit error locations are p and p+b.

In addition, in Error Pattern 3, the error location number P corresponding to the syndrome is in the range of 178 to 233. If the FEC block includes a 2-bit error and the syndrome is indicated as α^{P+178}, the error locations are p and p+19. Note that, if the polynomial used for scrambling is the polynomial x^{a}+x^{b}+1, the bit error locations are p and p+(a−b).

In summary, the bit error location or the bit error locations in each of the error patterns are as follows.

Error Pattern 1: error location is p

Error Pattern 2: error locations are p and p+39

Error Pattern 3: error locations are p and p+19

In the exemplary embodiment, the syndromes and the bit error location numbers are associated with each other in advance in accordance with the error pattern.

Here, the association between the syndromes and the bit error location numbers will be described.

For example, if the error pattern is Error Pattern 2, the syndrome corresponding to a bit error location number P1 representing the 2-bit error locations p and p+39 is indicated by the exclusive OR of the syndrome corresponding to the 1-bit error location p and the 1-bit error location p+39.

In addition, if the error pattern is Error Pattern 3, the syndrome corresponding to a bit error location number P2 representing the 2-bit error locations p and p+19 is indicated by the exclusive OR of the syndrome corresponding to the 1-bit error location p and the 1-bit error location p+19.

Accordingly, the syndromes and the bit error location numbers are associated with each other in the table in such a manner that the bit error location number P1 and the bit error location number P2 satisfy the following conditions.

P1,P2>n, and |P1−P2|>n

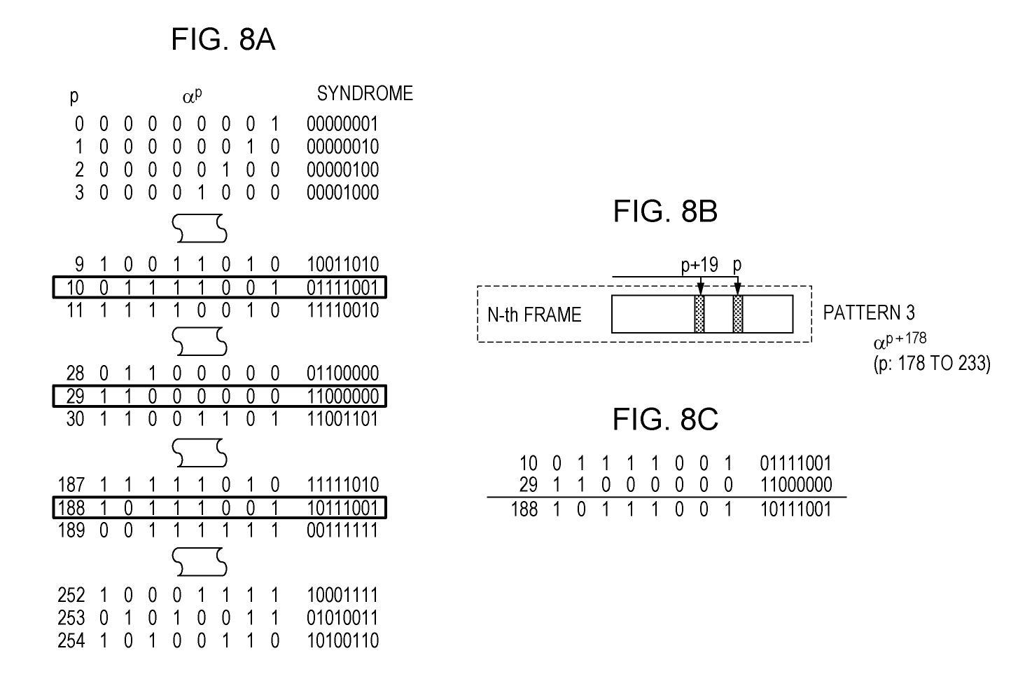

FIGS. 8A, 8B, and 8C illustrate relationships between the syndromes corresponding to the bit error location numbers P representing the 2-bit error locations p and p+19 and the actual bit error locations p and p+19.

As illustrated in FIGS. 8A, 8B, and 8C, if the error pattern is Error Pattern 3, when an error occurs at the 10-th bit and the 29-th bit, the syndrome is the 188-th bit stream (the error location number P is 188). Since the error location number P is 188, on the basis of α^{P+178} (p: 178 to 233), the error pattern is determined to be the Error Pattern 3. Then, in accordance with the error pattern, the actual error location p is calculated (188-178=10). In addition, the other error location p+19 is calculated (10+19=29). Then, the 10-th bit and 29-th bit that have been subjected to calculation are corrected by the correcting unit 158, which will be described later.

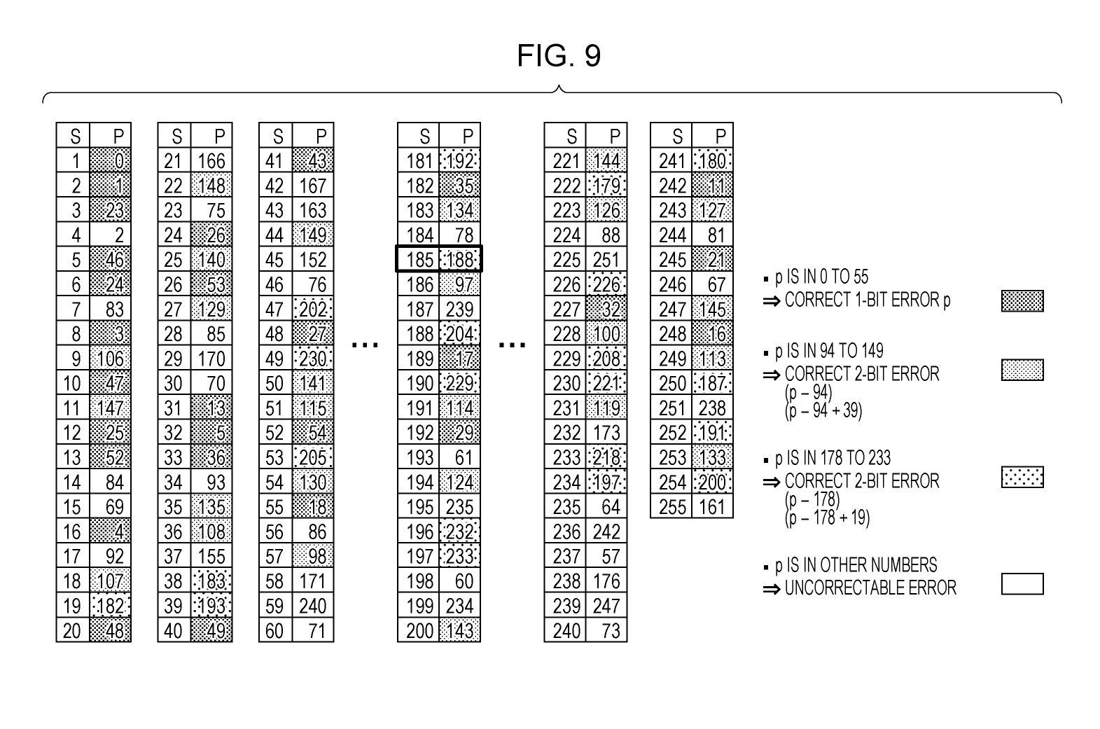

FIG. 9 illustrates an exemplary table in which syndromes and bit error location numbers are associated with each other in advance. In the table illustrated in FIG. 9, 255 byte addresses representing 8-bit syndromes are associated with error location numbers P in advance. Byte addresses S in the table illustrated in FIG. 9 are decimal numbers corresponding to binary numbers of the syndromes.

For example, as illustrated in FIG. 9, if the calculated syndrome is “10111001”, since the syndrome “1100100100101” is represented by a byte address “185” in FIG. 9, it is understood that the error location number P is “188”.

As illustrated in FIG. 9, in the case where the error location number P is in the range of 0 to 55, the error pattern corresponds to Error Pattern 1, and the error location p is corrected by the correcting unit 158. In addition, in the case where the error location number P is in the range of 94 to 149, the error pattern corresponds to Error Pattern 2, and an error location (p−94) and an error location (p−94+39) are corrected by the correcting unit 158. In addition, in the case where the error location number P is in the range of 178 to 223, the error pattern corresponds to Error Pattern 3, and an error location (p−178) and an error location (p−178+19) are corrected by the correcting unit 158. Furthermore, in the case where the error location number P is a number included in none of the ranges of 0 to 55, 94 to 149, and 178 to 223, the error is determined to be an uncorrectable error.

Accordingly, the error detecting unit 156 specifies the bit error location in the descrambled data in accordance with the table in which the syndromes and the bit error location numbers are associated with each other in advance and the error pattern corresponding to the syndrome calculated by the ECC comparing unit 154, and outputs the specified bit error location to the correcting unit 158.

If the syndrome calculated by the ECC comparing unit 154 does not exist in the table including 255 patterns represented by 8 bits, the error detecting unit 156 detects an error of 2 or more bits on the transmission path and outputs information indicating the error of 2 or more bits on the transmission path to the error output unit 160.

The correcting unit 158 inverts, in the descrambled data stored in the buffer 150, the bit corresponding to the error location according to the information output from the error detecting unit 156, thereby correcting the bit error in the descrambled data.

If the error detecting unit 156 has output the information indicating the error of 2 or more bits on the transmission path, the error output unit 160 outputs the information indicating the error of 2 or more bits on the transmission path as an uncorrectable error.

After the completion of error correction including the case of no errors, the data output unit 162 sequentially outputs the descrambled data stored in the buffer 150.

Operation of Information Transmission System

Next, an operation of the information transmission system 10 will be described. As described above, the operation of the information transmission system 10 includes processes on the encoding device 12 side and processes on the decoding device 14 side.

Processes on Encoding Device Side

First, processes performed on the encoding device 12 side will be described.

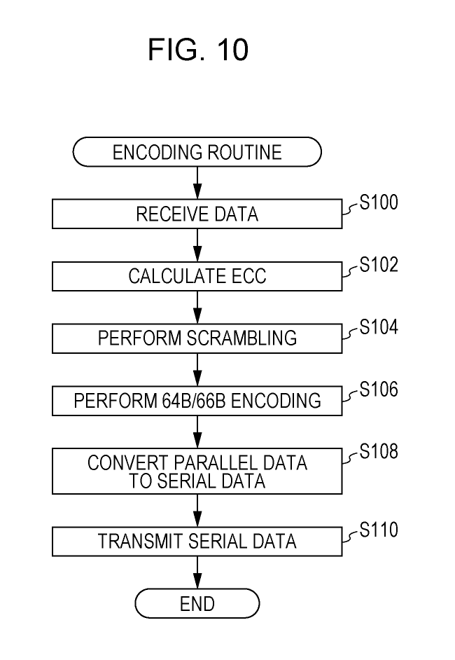

FIG. 10 is a flowchart illustrating an exemplary procedure of an encoding routine executed by the encoding device 12. Upon reception of parallel data to be encoded, the encoding device 12 executes the encoding routine illustrated in FIG. 10.

In step S100, the data receiving unit 120 receives parallel transmission data.

In step S102, the ECC calculating unit 124 calculates an error correcting code to be added to the transmission data on the basis of the parallel transmission data received by the data receiving unit 120 and according to the 8-degree cyclic code generator polynomial represented by the above Expression (1).

In step S104, the scrambler unit 126 scrambles the transmission data received in step S100 and the error correcting code calculated in step S102 according to the above Expression (3), the transmission data to which the error correcting code has been added.

In step S106, the 64B/66B encoding unit 128 encodes, in accordance with a 64B/66B encoding scheme, the transmission data scrambled in step S104 and transforms the number of bits.

In step S108, the parallel-to-serial (P/S) converting unit 130 converts the parallel data, obtained as a result of the transformation in step S106, to a serial bit stream.

In step S110, the transmitting unit 132 outputs the serial data, obtained as a result of the conversion in step S108, to the transmission path 16 and ends the encoding routine.

Processes on Decoding Device Side

Next, processes performed on the decoding device 14 side will be described.

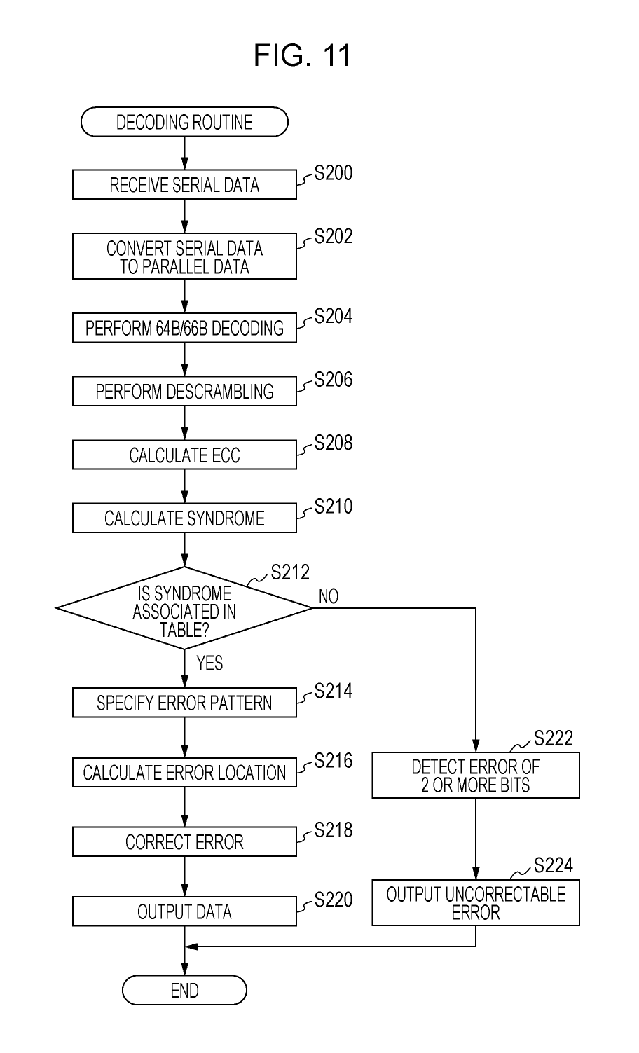

FIG. 11 is a flowchart illustrating an exemplary procedure of a decoding routine executed by the decoding device 14. Upon reception of data to be decoded, the decoding device 14 executes the decoding routine illustrated in FIG. 11.

In step S200, the receiving unit 140 receives serial data transmitted from the encoding device 12 through the transmission path 16.

In step S202, the serial-to-parallel (S/P) converting unit 142 converts the serial data received in step S200 to parallel data. The byte alignment of the parallel data is carried out by a 64B/66B encoding scheme.

In step S204, the 64B/66B decoding unit 144 decodes, in accordance with a 64B/66B encoding scheme with the number of bits transformed, the parallel data obtained in step S202 and outputs the resulting data as received data and an error correcting code.

In step S206, the descrambler unit 146 descrambles the received data and error correcting code decoded in step S204. In addition, the descrambler unit 146 causes the decoded descrambled data and error correcting code to be stored in the buffer 150.

In step S208, the ECC calculating unit 152 acquires the descrambled data stored in the buffer 150 and calculates an error correcting code on the basis of the acquired descrambled data and according to the 8-degree cyclic code generator polynomial G(x) represented by the above Expression (1).

In step S210, the ECC comparing unit 154 calculates a syndrome on the basis of the error correcting code stored in the buffer 150 and the error correcting code calculated in step S208.

In step S212, from the syndrome calculated in step S210 and on the basis of a table in which syndromes and numbers corresponding to bit error locations are associated with each other in advance, the error detecting unit 156 determines whether or not the syndrome calculated in step S210 is associated with a preset byte address. If the calculated syndrome is associated with the preset byte address, the process proceeds to step S214. If the calculated syndrome is not associated with the preset byte address, the process proceeds to step S222.

In step S214, on the basis of a table in which syndrome numbers P and word addresses representing the syndromes are associated with each other in advance and from the syndrome calculated in step S210, the error detecting unit 156 specifies the error pattern in accordance with a calculated syndrome number P.

In step S216, in accordance with the error pattern specified in step S214, the error detecting unit 156 specifies the actual bit error location and outputs information indicating the actual bit error location to the correcting unit 158.

In step S218, the correcting unit 158 inverts, in the descrambled data stored in the buffer 150, the bit corresponding to the error location according to the information output in step S216, thereby correcting the bit error in the descrambled data.

In step S220, the data output unit 162 outputs the descrambled data stored in the buffer 150 and ends the decoding routine.

In step S222, the error detecting unit 156 detects an error of 2 or more bits on the transmission path and outputs information indicating the error of 2 or more bits on the transmission path.

In step S224, the error output unit 160 outputs the information indicating the error of 2 or more bits output in step S222 as an uncorrectable error and ends the decoding routine.

It is needless to say that the configuration of the information transmission system described above in the exemplary embodiment is an exemplary configuration and may be modified without departing from the spirit of the present invention. For example, although the information transmission system including the encoding device and the decoding device has been described, a device including both an encoding unit and a decoding unit may be provided, and such devices may perform serial transmission in the information transmission system. The transformation of the number of bits is not limited to 64B/66B transformation and other transformation of the number of bits is also possible.

Although the exemplary embodiment has described above the example of using the above Expression (3) as an example of the polynomial x^{a}+x^{b}+1 used for scrambling, the polynomial x^{a}+x^{b}+1 used for scrambling is not limited thereto, and a and b may be a combination of certain numbers.

For example, in the case of scrambling according to a polynomial x⁵⁷+x^{b}+1, the index b may be any of 9, 10, 12, 19, 38, 45, 47, and 48.

In addition, in the case of scrambling according to a polynomial x⁵⁸+x^{b}+1, the index b may be any of 8, 10, 19, 24, 34, 39, 48, and 50.

In addition, in the case of scrambling according to a polynomial x⁵⁹+x^{b}+1, the index b may be any of 8, 14, 55, and 51.

In addition, in the case of scrambling according to a polynomial x⁶⁰+x^{b}+1, the index b may be any of 13, 15, 45, and 47.

In addition, in the case of scrambling according to a polynomial x⁶¹+x^{b}+1, the index b may be any of 13 and 48.

In addition, in the case of scrambling according to a polynomial x⁶²+x^{b}+1, the index b may be any of 9, 12, 21, 41, 50, and 53.

In addition, in the case of scrambling according to a polynomial x⁶³+x^{b}+1, the index b may be any of 12, 21, 42, and 51.

In addition, in the case of scrambling according to a polynomial x⁶⁴+x^{b}+1, the index b may be any of 14, 19, 45, and 50.

It is possible to provide any of the above exemplary embodiments of the present invention not only by using a communication medium but also by being stored in a recording medium such as a compact disc read only memory (CDROM).

The foregoing description of the exemplary embodiment of the present invention has been provided for the purposes of illustration and description. It is not intended to be exhaustive or to limit the invention to the precise forms disclosed. Obviously, many modifications and variations will be apparent to practitioners skilled in the art. The embodiment was chosen and described in order to best explain the principles of the invention and its practical applications, thereby enabling others skilled in the art to understand the invention for various embodiments and with the various modifications as are suited to the particular use contemplated. It is intended that the scope of the invention be defined by the following claims and their equivalents.

What is claimed is:

1. A decoding device that receives transmission data obtained by scrambling according to a polynomial x^{a}+x^{b}+1 where a and b are each an integer, a>b, and a≠2b, the decoding device comprising:
a receiving unit that receives data obtained by performing scrambling for a block in which an error correcting code has been added to the transmission data of (n−8) bits where n<a, the error correcting code being calculated according to a cyclic code generator polynomial X⁸+X⁶+X⁴+X³+1;
an error detecting unit that calculates, on the basis of a table, an error location in descrambled data obtained by descrambling the received data, in accordance with an error pattern corresponding to a syndrome calculated on the basis of the error correcting code from the descrambled data and an error correcting code calculated from the descrambled data, the table including
syndromes and bit error location numbers that are associated with each other in advance where
a syndrome corresponding to a bit error location number P1 representing 2-bit error locations p where p≦n and p+b including a 1-bit error location p and a 1-bit error location p+b is indicated by an exclusive OR of a syndrome corresponding to the 1-bit error location p and a syndrome corresponding to the 1-bit error location p+b,
a syndrome corresponding to a bit error location number P2 representing 2-bit error locations p and p+(a−b) including the 1-bit error location p and a 1-bit error location p+(a−b) is indicated by an exclusive OR of a syndrome corresponding to the 1-bit error location p and a syndrome corresponding to the 1-bit error location p+(a−b), and
the syndromes and the bit error location numbers are associated with each other in such a manner that the bit error location number P1 and the bit error location number P2 satisfy P1, P2>n and |P1−P2|>n; and
a correcting unit that corrects the descrambled data at the error location calculated by the error detecting unit.

2. The decoding device according to claim 1, wherein, if the calculated syndrome is not associated with the bit error location numbers included in the table except all-‘0’, the error detecting unit detects an uncorrectable error in the data.

3. An information transmission system comprising:
the decoding device according to claim 1; and
an encoding device including
a converting unit that adds, to the transmission data, the error correcting code calculated according to the cyclic code generator polynomial x⁸+x⁶+x⁴+x³+1 to generate error-correcting-code-added transmission data and scrambles the error-correcting-code-added transmission data to obtain the data, and
a transmitting unit that transmits the data obtained by the converting unit.

4. A decoding method for a decoding device that receives transmission data obtained by scrambling according to a polynomial x^{a}+x^{b}+1 where a and b are each an integer, a>b, and a≠2b, the method comprising:
receiving data obtained by performing scrambling for a block in which an error correcting code has been added to the transmission data of (n−8) bits where n<a, the error correcting code being calculated according to a cyclic code generator polynomial x⁸+x⁶+x⁴+x³+1;
calculating, on the basis of a table, an error location in descrambled data obtained by descrambling the received data, in accordance with an error pattern corresponding to a syndrome calculated on the basis of the error correcting code from the descrambled data and an error correcting code calculated from the descrambled data, the table including
syndromes and bit error location numbers that are associated with each other in advance where
a syndrome corresponding to a bit error location number P1 representing 2-bit error locations p where p≦n and p+b including a 1-bit error location p and a 1-bit error location p+b is indicated by an exclusive OR of a syndrome corresponding to the 1-bit error location p and a syndrome corresponding to the 1-bit error location p+b,
a syndrome corresponding to a bit error location number P2 representing 2-bit error locations p and p+(a−b) including the 1-bit error location p and a 1-bit error location p+(a−b) is indicated by an exclusive OR of a syndrome corresponding to the 1-bit error location p and a syndrome corresponding to the 1-bit error location p+(a−b), and
the syndromes and the bit error location numbers are associated with each other in such a manner that the bit error location number P1 and the bit error location number P2 satisfy P1, P2>n and |P1−P2|>n; and
correcting the descrambled data at the calculated error location.

5. A non-transitory computer readable medium storing a program causing a computer to execute a process for a decoding device that receives transmission data obtained by scrambling according to a polynomial x^{a}+x^{b}+1 where a and b are each an integer, a>b, and a≠2b, the process comprising:
receiving data obtained by performing scrambling for a block in which an error correcting code has been added to the transmission data of (n−8) bits where n<a, the error correcting code being calculated according to a cyclic code generator polynomial x⁸+x⁶+x⁴+x³+1;
calculating, on the basis of a table, an error location in descrambled data obtained by descrambling the received data, in accordance with an error pattern corresponding to a syndrome calculated on the basis of the error correcting code from the descrambled data and an error correcting code calculated from the descrambled data, the table including
syndromes and bit error location numbers that are associated with each other in advance where
a syndrome corresponding to a bit error location number P1 representing 2-bit error locations p where p≦n and p+b including a 1-bit error location p and a 1-bit error location p+b is indicated by an exclusive OR of a syndrome corresponding to the 1-bit error location p and a syndrome corresponding to the 1-bit error location p+b,
a syndrome corresponding to a bit error location number P2 representing 2-bit error locations p and p+(a−b) including the 1-bit error location p and a 1-bit error location p+(a−b) is indicated by an exclusive OR of a syndrome corresponding to the 1-bit error location p and a syndrome corresponding to the 1-bit error location p+(a−b), and
the syndromes and the bit error location numbers are associated with each other in such a manner that the bit error location number P1 and the bit error location number P2 satisfy P1, P2>n and |P1−P2|>n; and
correcting the descrambled data at the calculated error location.
